(19) United States
(12) Patent Application Publication
(10) Pub. No.: US 2013/0153934 A1
(43) Pub. Date: Jun. 20, 2013

(54) PHOTOVOLTAIC DEVICES WITH OFF-AXIS IMAGE DISPLAY

(71) Applicants: Matthew Meitl, Durham, NC (US); Joseph Carr, Chapel Hill, NC (US); Scott Burroughs, Durham, NC (US)

(72) Inventors: Matthew Meitl, Durham, NC (US); Joseph Carr, Chapel Hill, NC (US); Scott Burroughs, Durham, NC (US)

(21) Appl. No.: 13/700,411

(22) PCT Filed: Jun. 7, 2011
(86) PCT No.: PCT/US11/39408

§ 371 Date: Feb. 11, 2013

Related U.S. Application Data
(60) Provisional application No. 61/352,028, filed on Jun. 7, 2010.

(51) Int. Cl. H01L 31/0232; H01L 31/173

(52) U.S. Cl. CPC H01L 31/0232; H01L 31/173
USPC 257/84; 438/24

(57) ABSTRACT

A concentrated photovoltaic and display apparatus includes a backplane substrate, a plurality of photovoltaic elements distributed over the backplane substrate, a plurality of display elements distributed over the backplane substrate between the photovoltaic elements, and an optical element positioned over the backplane substrate, the photovoltaic elements, and the display elements. The optical element is configured to concentrate incident light propagating in a direction substantially parallel to an optical axis thereof onto the photovoltaic elements. The optical element is further configured to direct light reflected or emitted from the display elements in a direction that is not substantially parallel to the optical axis of the optical element. Related fabrication methods and arrays including the apparatus are also discussed.

### CLAIM OF PRIORITY

The present application claims priority from U.S. Provisional Patent Application No. 61/352,028 entitled “Photovoltaic Device with Off-Axis Image Display,” filed with the United States Patent and Trademark Office on Jun. 7, 2010, the disclosure of which is incorporated by reference herein.

### FIELD OF THE INVENTION

The present invention relates to photovoltaic devices, and more particularly, to concentrated photovoltaic devices incorporating integrated display elements.

### BACKGROUND OF THE INVENTION

Large substrates with electronically active components arranged on or distributed over the extent of the substrate may be used in a variety of electronic systems, for example imaging devices such as flat-panel liquid crystal or OLED display devices and/or in digital radiographic plates. Large substrates with electrically active components are also found in flat-panel solar cells.

Concentrated photovoltaic (CPV) solar cell systems use lenses or mirrors to focus a relatively large area of sunlight onto a relatively small solar cell. The solar cell converts the focused sunlight into electrical power. By optically concentrating the sunlight into a smaller area, fewer and smaller solar cells with greater conversion performance can be used to create more efficient photovoltaic systems at lower cost. To increase or maximize the performance of concentrated photovoltaic systems, CPV systems can be mounted on a tracking system that aligns the CPV system optics with a light source (typically the sun). To reduce weight and size, Fresnel lenses can be used with CPV systems.

Concentrated photovoltaic systems are typically used by industrial-scale power-generating utilities and can occupy significant area in a landscape. The visual appearance of these systems can dominate the landscape and be overly conspicuous, ugly, or monotonous, leading to resistance to such systems by the public. Moreover, it may be difficult to use the space occupied by or around such CPV systems for other purposes at the same time without interfering with the light-collecting ability of the CPV system or decreasing the CPV system efficiency.

It is known to make images of solar arrays with both earth-based and space-based image capture to determine underperformance or performance variations through observing varying thermal and other signature images of the solar arrays and portions thereof. However, capturing remote images of solar arrays to determine their performance does not improve their appearance or provide additional uses for the arrays.

U.S. Patent Application Publication No. 2007/0277810 entitled “Solar Panel” discloses a solar panel having a panel front and a panel back comprising an array of solar cells with spacings between them and an element comprising a visually distinguishable feature. At least the front is capable of converting solar light into electrical energy. The visually distinguishable feature is visible from the panel front and can include a design, color, pattern, picture, advertisement, text, and so forth. In one embodiment, the feature is located between the solar cells of the array and in another embodiment the feature may comprise one or more LEDs or LCDs. However, this system cannot efficiently collect sunlight and at the same time provide readily visible distinguishable features, as at least some efficiency is sacrificed by providing the spacings between the solar cells so that the feature on the panel back is visible.

### SUMMARY OF THE INVENTION

It should be appreciated that this Summary is provided to introduce a selection of concepts in a simplified form, the concepts being further described below in the Detailed Description. This Summary is not intended to identify key features or essential features of this disclosure, nor is it intended to limit the scope of the disclosure.

According to some embodiments of the present invention, a photovoltaic and display apparatus includes a backplane substrate, a plurality of photovoltaic elements arranged on the backplane substrate, a plurality of display elements arranged on the backplane substrate between the photovoltaic elements, and an optical element positioned over the backplane substrate, the photovoltaic elements, and the display elements. The optical element is configured to direct incident light propagating in a direction substantially parallel to an optical axis thereof away from the display elements and concentrate the incident light onto the photovoltaic elements. The optical element is further configured to direct light reflected or emitted from the display elements in a direction that is not substantially parallel to the optical axis of the optical element.

In some embodiments, the optical element includes a Fresnel lens, an array of Fresnel lenses, a lens, an array of lenslets, a plano-convex lens, an array of plano-convex lenses, a double-convex lens, an array of double-convex lenses, or an array of crossed panoptic lenses.

In some embodiments, the photovoltaic elements and the display elements are arranged on coplanar surfaces of the backplane substrate.

In some embodiments, the photovoltaic elements are not substantially visible when viewed along one or more directions that are not parallel to the optical axis.

In some embodiments, the optical element is configured to magnify the photovoltaic elements when viewed along the direction substantially parallel to the optical axis, and to magnify the display elements when viewed along the one or more directions that are not parallel to the optical axis.

In some embodiments, the photovoltaic elements are arranged in an array on the backplane substrate. The optical element may include an array of lenses, and each of the lenses may concentrate or focus the incident light that is substantially parallel to the respective optical axis thereof onto a corresponding one of the photovoltaic elements.

In some embodiments, the apparatus includes a plurality of receiver substrates mounted on the backplane substrate. One or more of the photovoltaic elements and/or display elements may be arranged on each of the receiver substrates.

In some embodiments, each of the photovoltaic elements is adjacent one or more of the display elements on the backplane substrate. For example, each of the photovoltaic elements may be adjacent first and second ones of the display elements. The first ones of the display elements may be associated with a first image that is visible from a first nonzero angle with respect to the optical axis, and the second ones of the display elements may be associated with a second image that is visible at a second, different nonzero angle with respect to the optical axis. The first and second nonzero angles may be complementary angles. The first and second ones of the display elements may be arranged on the backplane substrate at different positions relative to the optical axis.

In some embodiments, each of the photovoltaic elements is adjacent two or more of the display elements, where the two or more of the display elements have a different color or image associated therewith.

In some embodiments, the display elements are passive reflectors. For example, the display elements may include an acrylic-epoxy blend.

In some embodiments, the display elements are active controllable elements.

In some embodiments, the display elements can be respectively controlled to emit light or to not emit light.

In some embodiments, the display elements can be respectively controlled to absorb light or to reflect light.

In some embodiments, each of the photovoltaic elements is adjacent three of the display elements, where the three of the display elements are configured to provide light of three different colors, respectively. For example, the three of the display elements may be spatially grouped into full-color pixels.

In some embodiments, the display elements are controlled by circuits in the photovoltaic elements.

In some embodiments, the photovoltaic elements and/or the display elements may be printable chiplets.

In some embodiments, the apparatus may be one of a plurality of modules of an array. The array may be configured to display a single image across the plurality of modules, and the display elements of the apparatus may provide a portion of the single image.

According to further embodiments of the present invention, a method of fabricating a concentrated photovoltaic and display apparatus includes providing a backplane substrate, providing a plurality of photovoltaic elements distributed over the backplane substrate, providing a plurality of display elements distributed over the backplane substrate between the photovoltaic elements, and providing an optical element over the backplane substrate, the photovoltaic elements, and the display elements. The optical element is configured to concentrate incident light propagating in a direction substantially parallel to an optical axis thereof onto the photovoltaic elements and away from the display elements. The optical element is further configured to direct light reflected or emitted from the display elements in a direction that is not substantially parallel to the optical axis of the optical element.

In some embodiments, providing the plurality of photovoltaic elements on the backplane substrate includes forming the plurality of photovoltaic elements in a wafer, releasing the photovoltaic elements from the wafer, adhering the photovoltaic elements to a stamp, and stamping the photovoltaic elements onto the backplane substrate.

In some embodiments, providing the plurality of photovoltaic elements on the backplane substrate includes forming the plurality of photovoltaic elements in a wafer, releasing the photovoltaic elements from the wafer, adhering the photovoltaic elements to a stamp, stamping the photovoltaic elements onto one or more receiver substrates, and affixing the one or more receiver substrates to the backplane substrate.

In some embodiments, stamping the photovoltaic elements onto one or more receiver substrates includes stamping the photovoltaic elements onto a single receiver substrate, and breaking the single receiver substrate into a plurality of individual receiver substrates. The individual receiver substrates may be affixed to the backplane substrate.

In some embodiments, each individual receiver substrate includes a single photovoltaic circuit, and the individual receiver substrate and the single photovoltaic circuit define one of the photovoltaic elements.

According to still further embodiments of the present invention, a concentrated photovoltaic and display system includes a plurality of backplane substrates, a plurality of photovoltaic elements distributed over each of the backplane substrates, a plurality of display elements distributed over each of the backplane substrates between the photovoltaic elements, and a respective optical element positioned over each of the backplane substrates and the photovoltaic elements and the display elements thereof. The respective optical element is configured to concentrate incident light propagating in a direction substantially parallel to an optical axis thereof onto the photovoltaic elements and away from the display elements of the corresponding backplane substrate. The respective optical element is configured to direct light reflected or emitted from the display elements of the corresponding backplane substrate in a direction that is not substantially parallel to the optical axis thereof.

In some embodiments, the plurality of backplane substrates is mounted in an array on a common support, and the array is configured to display a single image across the plurality of backplane substrates. For example, one or more of the plurality of display elements of each of the backplane substrates may define a different portion of the single image, and the different portion of the single image may be visible when viewed along the direction that is not substantially parallel to the respective optical axis of the optical element thereof. Additionally or alternatively, one or more of the plurality of display elements of each of the backplane substrates may define an entirety of the single image, and a different portion of the single image may be visible on each of the backplane substrates based on differences in viewer perspective to the array.

According to other embodiments of the present invention, a concentrated photovoltaic and display apparatus, includes a backplane substrate, one or more receiver substrates mounted to the backplane substrate, a plurality of photovoltaic elements distributed over each of the receiver substrates; a plurality of display elements distributed over the backplane substrate or each of the receiver substrates between the photovoltaic elements, and an optical element located over the backplane substrate, the photovoltaic elements, and the display elements. The optical element is configured to concentrate incident light propagating in a direction substantially parallel to an optical axis thereof onto the photovoltaic elements and away from the display elements. The optical element is further configured to direct light reflected or emitted from the display elements in a direction that is not substantially parallel to the optical axis of the optical element.

According to still other embodiments of the present invention, a concentrated photovoltaic and display apparatus, includes a backplane substrate, one or more receiver substrates mounted to the backplane substrate, a photovoltaic circuit located on each of the receiver substrates such that each of the receiver substrates has a single photovoltaic circuit forming a photovoltaic element, a plurality of display elements distributed over the backplane substrate or receiver substrates between the photovoltaic elements, and an optical element located over the backplane substrate, the photovoltaic elements, and the display elements. The optical element is configured to concentrate incident light propagating in a direction substantially parallel to an optical axis thereof onto the photovoltaic elements and away from the display elements. The optical element is further configured to direct light reflected or emitted from the display elements in a direction that is not substantially parallel to the optical axis of the optical element.

According to yet further embodiments of the present invention, a concentrator-type photovoltaic device includes a substrate having a photovoltaic element and at least one display element arranged alongside one another on a surface of the substrate, and an optical element positioned over the surface of the substrate. The optical element is configured to direct incident light propagating on-axis with respect to an optical axis thereof away from the at least one display element and onto the photovoltaic element, and to direct light reflected or emitted from the at least one display element off-axis with respect to the optical axis.

Accordingly, embodiments of the present invention provide a high-performance, efficient photovoltaic device and a display element on the same backplane.

Other methods and/or devices according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a cross section illustrating an embodiment of the present invention having display and photovoltaic elements;

FIG. 2 is a cross section illustrating an embodiment of the present invention having a display element associated with each photovoltaic element;

FIG. 3 is a cross section illustrating an embodiment of the present invention having two display elements located between photovoltaic elements;

FIG. 4 is a cross section illustrating an embodiment of the present invention having three display elements located between photovoltaic elements;

FIG. 5 is a top view illustrating an embodiment of the present invention having a single display element and corresponding to the cross section of FIG. 1;

FIG. 6 is a top view illustrating an embodiment of the present invention having a display element associated with each photovoltaic element and corresponding to the cross section of FIG. 2;

FIG. 7 is a top view illustrating an embodiment of the present invention having three display elements;

FIG. 8 is a top view illustrating the appearance of an embodiment of the present invention at a normal angle;

FIG. 9 is a top view illustrating the appearance of an embodiment of the present invention at an off-axis angle;

FIG. 10 is a perspective illustrating an array of display elements with chiplet display element controllers located on a backplane substrate according to an embodiment of the present invention;

FIG. 11 is a perspective illustrating an array of photovoltaic and display element chiplets located on a backplane substrate according to an embodiment of the present invention;

FIG. 12 is a top view illustrating an optical element comprising an array of Fresnel lenses useful with an embodiment of the present invention;

FIG. 13 is a cross section illustrating a pattern of emitted light rays according to an embodiment of the present invention;

FIG. 14 is a perspective illustrating a pattern of light emitters viewed from the left according to an embodiment of the present invention;

FIG. 15 is a perspective illustrating a pattern of light emitters viewed from the right according to an embodiment of the present invention;

FIG. 16 is a perspective illustrating an embodiment of the present invention mounted on a support;

FIGS. 17A-17C are flow diagrams illustrating a method of making an apparatus according to an embodiment of the present invention;

FIG. 18A is a cross section of an optical element with lenslets according to an embodiment of the present invention;

FIG. 18B is a top view of an optical element with circular lenslets in a hexagonal close-packed array according to an embodiment of the present invention;

FIG. 18C is a top view of an optical element with square lenslets in a regular rectangular array according to an embodiment of the present invention;

FIG. 19 is a cross section of a backplane substrate with a planarizing layer according to an embodiment of the present invention;

FIG. 20 is a top view of an array of concentrated photovoltaic and display apparatuses according to an embodiment of the present invention;

FIGS. 21A and 21B are flow diagrams illustrating a method of making an apparatus according to an embodiment of the present invention;

FIG. 22 is a perspective of a backplane substrate with an array of receiver substrates according to an embodiment of the present invention; and

FIG. 23 is a perspective of a backplane substrate with an array of receiver substrates having photovoltaic circuits according to an alternative embodiment of the present invention.

The figures are not drawn to scale since the individual elements of the drawings have too great a size variation to permit depiction to scale.

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “in contact with” or “connected to” or “coupled to” another element, it can be directly contacting or connected to or coupled to the other element or intervening elements may be present. In contrast, when an element is referred to as being “in direct contact with” or “directly connected to” or “directly coupled to” another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “under” or “lower” or “bottom,” and “over” or “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. In other words, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

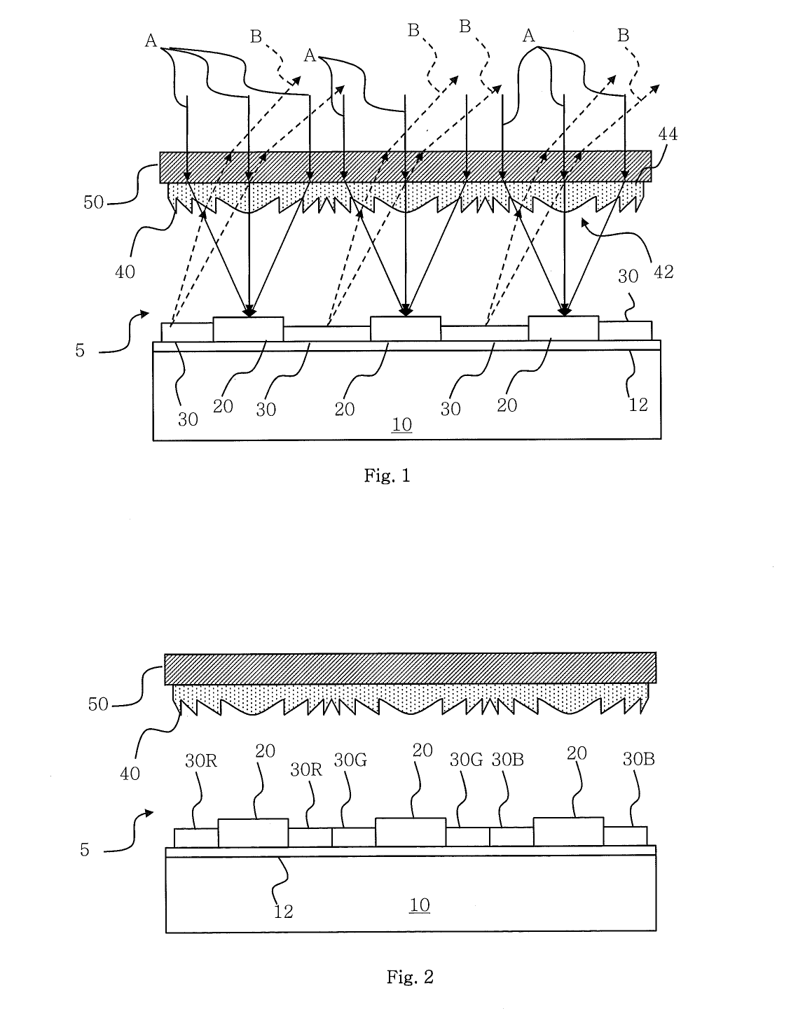

Referring to the cross section of FIG. 1, a photovoltaic and display apparatus 5 according to an embodiment of the present invention comprises a backplane substrate 10, a plurality of photovoltaic elements 20 distributed over the backplane substrate 10, a plurality of display elements 30 distributed over the backplane substrate 10 between the photovoltaic elements 20, and an optical element 40 located over the backplane substrate 10, the photovoltaic elements 20, and the display elements 30. The optical element 40 is designed to direct normally incident light A onto the photovoltaic elements 20 and the optical element 40 is designed to direct light B reflected or emitted from the display elements 30 in a direction away from the normal. A cover 50 affixed to the backplane substrate 10 can protect the photovoltaic and display apparatus 5. The optical element 40 can be affixed to the cover 50. Incident light A and emitted or reflected light B pass through the optical element 40.

The photovoltaic elements 20 can include photovoltaic circuits responsive to incident radiation to produce electrical current mounted directly on the backplane substrate 10 or on an intermediate structure or structures that are mounted to the backplane substrate 10. In any case, the photovoltaic elements 20 are distributed over the backplane substrate 10 and the display elements 30 distributed over the backplane substrate 10 between the photovoltaic elements 20. A plurality of optical elements 40 can be employed and can be individually associated with each photovoltaic element 20.

The photovoltaic elements 20 can form a periodic or regular, sparse array on the backplane substrate 10, for example occupying less than 25% of the backplane substrate area, less than 10% of the backplane substrate area, or even less than 5% of the backplane substrate area. The actual area covered by the photovoltaic elements 20 can depend on the size of the photosensitive area in the photovoltaic elements 20, the resolving power of the optical element 40, and the distance between the optical element 40 and the photovoltaic elements 20, as well as other manufacturing process issues. In one embodiment of the present invention, the photovoltaic elements 20 and display elements 30 are at a focal plane of the optical element 40. In other embodiments, however, the photovoltaic elements 20 and display elements 30 may be provided on a common plane that does not correspond to the focal plane of the optical element 40.

As used herein, a normal is an angle that is substantially orthogonal to a substrate, which is an angle of about 90 degrees with respect to the surface of the substrate. For example, the light ray A is normally incident on the photovoltaic and display apparatus 5 because the angle at which it strikes the photovoltaic and display apparatus 5 is at about 90 degrees to the surface of the cover 50 and the back side of the optical element 40. A direction away from the normal is an angle that is not at about 90 degrees with respect to the surface of the substrate. For example, the light ray B leaves the photovoltaic and display apparatus 5 at an angle that is not about 90 degrees to the surface of the cover 50 or the flat back surface 44 of the optical element 40 affixed to the cover 50. The optical element 40 can include lenses or lens-like elements that have an optical axis. Thus light rays that propagate substantially parallel to the optical axis of the optical element 40 are considered ‘on-axis’ light rays (e.g., light rays A), and light rays that do not propagate substantially parallel to the optical axis of the optical element 40 are considered ‘off-axis’ (e.g. light rays B).

It is recognized that optical elements and alignments are imperfect in any practical system. As such, incident light described herein as having a direction “substantially parallel” to the optical axis of an optical element 40 may not propagate exactly parallel to the optical axis, e.g., the incident light may not strike the photovoltaic and display apparatus 5 at exactly 90 degrees. For example, in some embodiments where the optical element 40 provides 1100 times (1100×) concentration of the incident light, light that is substantially parallel to the optical axis may include light that is ±0.8° from the normal. Also, in other embodiments where the optical element 40 provides 1000 times (1000×) concentration of the incident light, light that is substantially parallel to the optical axis may include light that is ±2° from the normal.

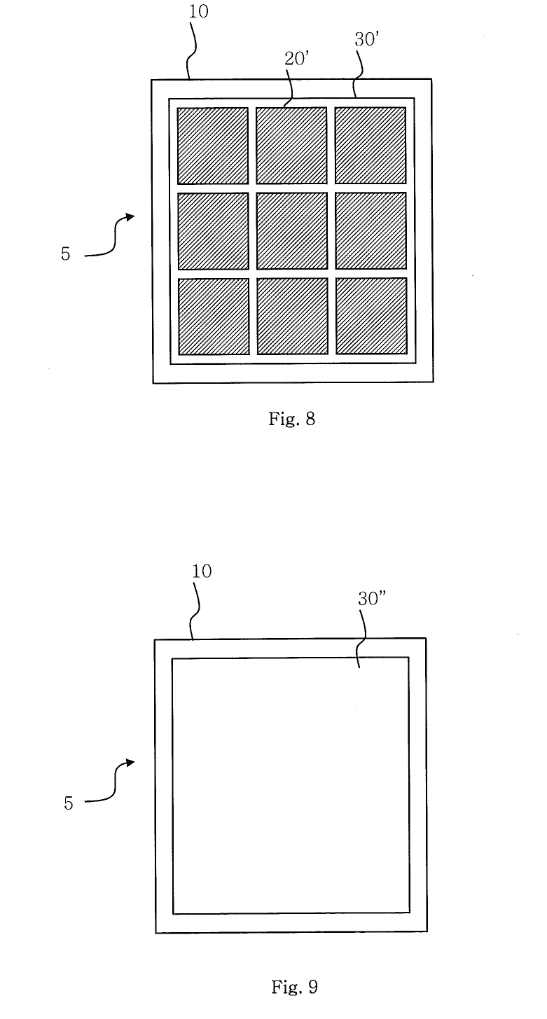

Referring to FIG. 8, a top view of the photovoltaic and display apparatus 5 at a normal angle will give the appearance of an array of large photovoltaic elements 20′ distributed over the backplane substrate 10, because the optical element can magnify the photovoltaic elements at a normal angle. The array of large photovoltaic elements 20′ will appear to cover much of the backplane substrate 10 area. Only a relatively small area of the display element 30′ will appear. In other words, the optical element re-directs incident light that is normal to the backplane substrate 10 away from the display elements 30′.

In contrast, referring to FIG. 9, a top view of the photovoltaic and display apparatus 5 at an off-axis angle will give the appearance of the display elements. The display elements 30″ will appear to cover the backplane substrate 10 area, such that the photovoltaic elements are not substantially visible or cannot be seen at most off-axis perspectives or distances. However, at very close distances, portions of the photovoltaic elements may be visible at some off-axis angles in some embodiments.

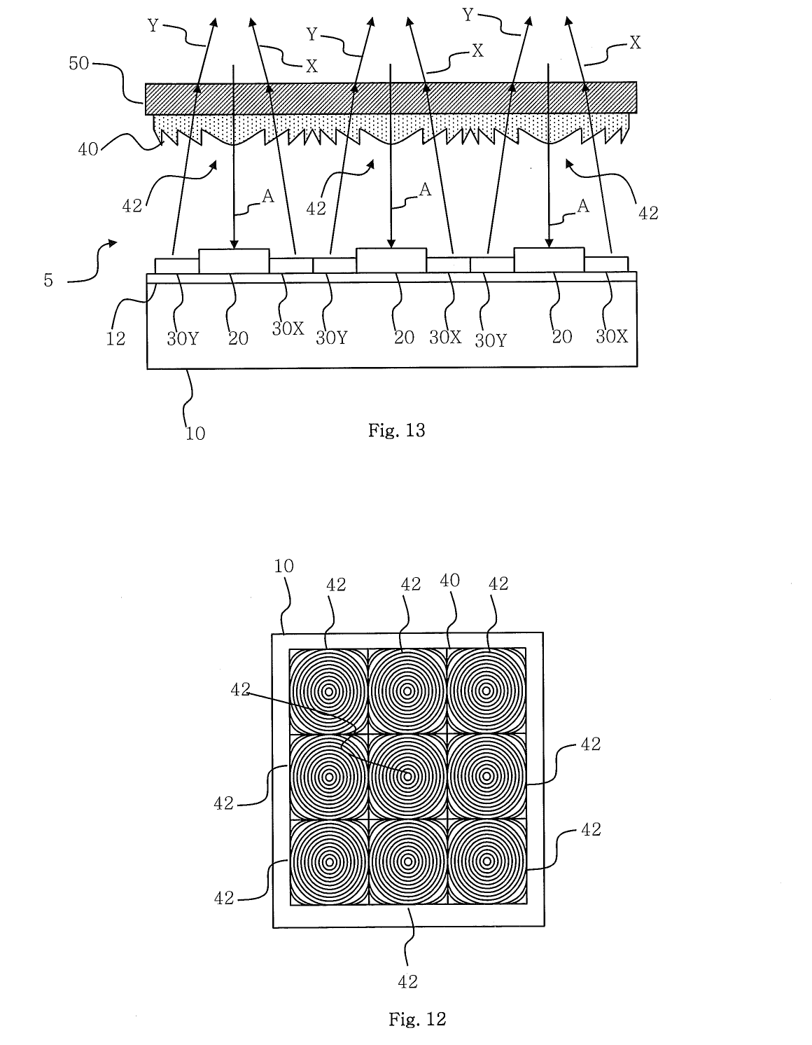

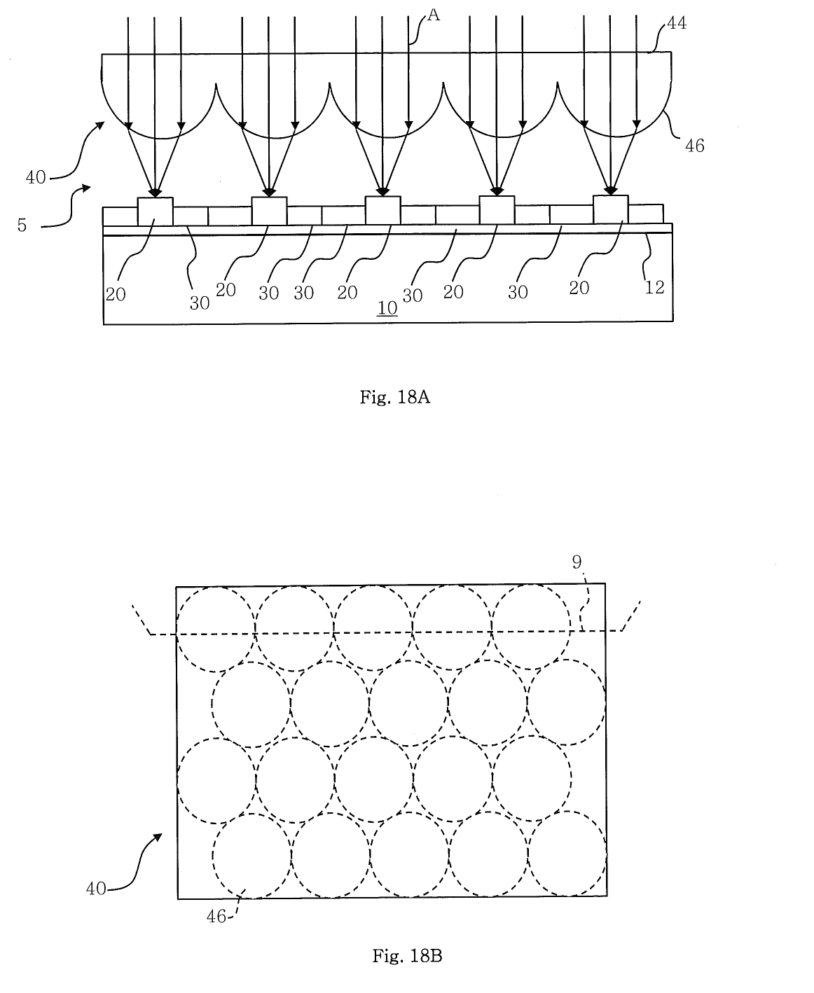

The optical element 40 can be any optical element configured to concentrate light on the photovoltaic elements. For example, the optical element 40 can be an array of lenslets or an array of Fresnel lenses 42. Alternatively, the optical element 40 can be a plano-convex lens or an array of plano-convex lenses, or a double-convex lens or an array of double-convex lenses. The optical element 40 can also include a series of crossed panoptic lenses, where a first panoptic lens and a second panoptic lens are arranged in an orthogonal manner. Fresnel lenses 42, as shown in FIG. 1, are useful when the desired lens is otherwise large or has a long focal length because a Fresnel lens has reduced mass and thickness. The cross section of FIG. 18A and the top view of FIG. 18B show an optical element 40 with an array of lenslets 46 with normally incident light concentrated on the photovoltaic elements 20. FIG. 18A is a cross section taken along line 9 of FIG. 18B. Arrays of Fresnel lenses and lenslets can be made from stamped, molded, cut, or etched polymer sheets. Referring to the top view of FIG. 12, an optical element 40 includes a regular array of Fresnel lenses 42. Referring back to FIG. 1, the plurality of photovoltaic elements 20 can be arranged in a regular array corresponding to the array of lenses so that normally incident ambient light A, for example sunshine, is directed onto each of the photovoltaic elements 20 in the array by a corresponding lens 42. The photovoltaic and display apparatus 5 of the present invention is a concentrated photovoltaic (CPV) system because it concentrates light incident over a relatively larger area (the extent of each lens 42) onto a relatively smaller area (the extent of a light-sensitive portion of a photovoltaic element 20).

Various arrangements, types and shapes of lenses can be employed in various embodiments of the present invention. As shown in FIG. 12, the optical element can include a plurality of separate lenses arranged in a regular rectangular array, the location of each lens being aligned with or otherwise corresponding to the location of a corresponding photovoltaic element. The lenses can be part of a common substrate or mounted on a common substrate. Alternatively, as shown in FIG. 18B, the optical element can include a plurality of separate lenses arranged in a hexagonal close-packed array, the location of each lens corresponding to the location of a corresponding photovoltaic element. Other arrangements of lenses can be employed so long as the location of each lens corresponds to the location of a corresponding photovoltaic element such that the lens concentrates incident light on a corresponding photovoltaic element.

The lenses can have a rectangular perimeter (as shown in FIGS. 12 and 18C) or a circular perimeter (as shown in FIG. 18B). The lens perimeter can be chosen to increase or maximize the concentration of incident light on the photovoltaic elements. The lenses can be of different types. A Fresnel lens is illustrated in FIGS. 1-4, 12, and 13 and an array of plano-convex lenses in FIG. 18A. Other lens types can be employed, although a positive lens is typically preferred to focus light. Biconvex, plano-convex, double-convex, crossed panoptic, spherical, and aspherical lenses can be employed depending on the optical design and constraints of the desired system. According to one embodiment of the present invention shown in FIG. 18C, an optical element 40 can include a regular, rectangular array of plano-convex lenses 47.

The photovoltaic element 20 can include a photovoltaic circuit constructed in a crystalline semiconductor material, such as silicon, gallium arsenide, or other III-V compound semiconductors. The photovoltaic circuits can have multiple layers with different crystalline structures, doped layers, and semiconductor junctions. The photovoltaic element 20 can include a chiplet and can include control circuitry as well as photovoltaic circuitry. A chiplet can be a small integrated circuit substrate that is too small to be positioned using conventional means but are stamped onto the backplane substrate 10 as described below. Alternatively, the photovoltaic element 20 can include a surface-mountable integrated circuit. Photovoltaic elements can comprise an integrated circuit alone or can comprise an assembly that includes a substrate, connecting wires, and photovoltaic circuits in an integrated circuit or in a separate non-integrated circuit.

Photovoltaic elements 20 can be adhered to the backplane substrate 10 with an adhesive layer 12 that is cured after the photovoltaic elements 20 are located on the adhesive layer 12 and backplane substrate 10. The display elements 30 can be separate elements, such as chiplets, likewise adhered to the backplane substrate 10 or can include thin-film circuits constructed on top of the adhesive layer 12 or backplane substrate 10, or both. The backplane substrate 10 can be for example, glass, metal, or polymer. Likewise the cover 50 can be, for example, transparent glass or polymer. Because the photovoltaic elements 20 can be located on the backplane substrate 10, rather than directly formed on the backplane substrate 10, the backplane substrate 10, in one embodiment of the present invention, does not have to be smooth or provide a hermetic seal.

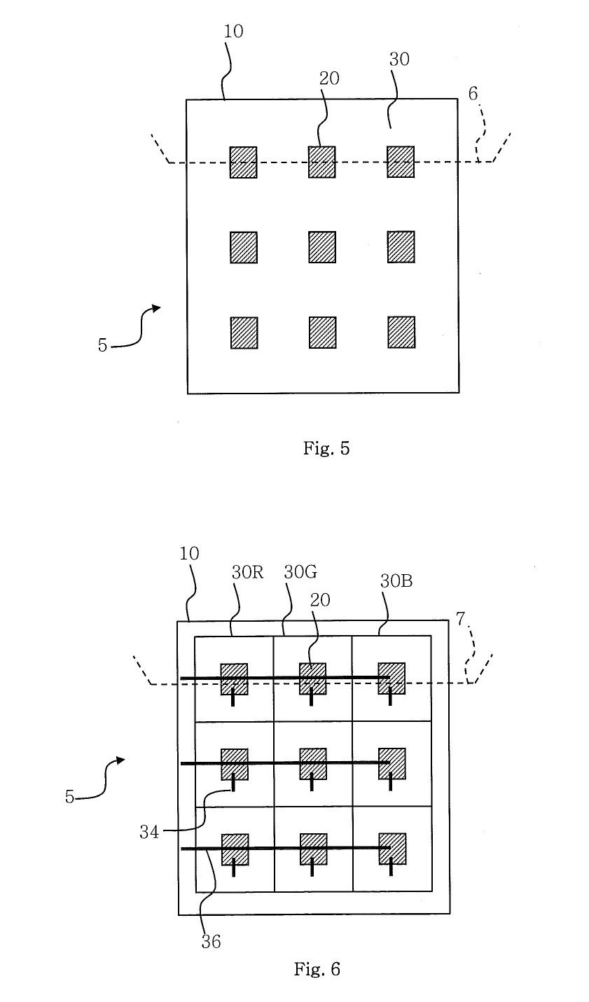

The display elements 30 can be implemented in a variety of ways according to a variety of embodiments of the present invention. In one embodiment, the display elements 30 are a single, passive reflective layer as shown in the cross section of FIG. 1 and the top view of FIG. 5. A passive reflective layer reflects incident light and is not controlled to change its behavior. The cross section 6 indicated in FIG. 5 corresponds to FIG. 1. The single reflective layer could be a single color, for example green or tan, chosen to blend in with the photovoltaic and display apparatus' surroundings, such as grass or sand. Alternatively, the single reflective layer could comprise a pattern of colors spelling out a message or depicting a static image or scene or otherwise communicating information to a viewer that views the photovoltaic and display apparatus at an off-axis angle. In one embodiment of the present invention, a passive reflective layer can include a solder-dam material, for example an acrylic-epoxy blend. In these cases, the passive, reflective layer is considered to provide a plurality of display elements 30, since the single reflective layer can be patterned. Thus, each of the display elements 30 can be the same, or different. The passive, reflective layer can be diffuse, so that reflections from the backplane can be seen at different angles, or specular, so that different reflections from different locations on the backplane substrate can be seen at different angles through the optical element 40. Reflective layers, both diffuse and specular, can be patterned, for example by screen printing, spray painting through masks, or by hand coloring. The backplane substrate 10 can be colored first and then provided with photovoltaic elements 20. The backplane substrate 10 can then be processed to provide electrical connections to collect current provided by the photovoltaic elements 20. Alternatively, the backplane substrate 10 can be provided with a passive reflective layer after the photovoltaic elements 20 are located, and before or after the photovoltaic elements 20 are electrically connected. Backplane substrates 10 can be processed using substrate processing methods used in the photolithographic arts to provide, for example, electrical connections, planarizing layers, and patterned metal layers.

In an alternative embodiment of the present invention, the display elements can be active elements rather than passive elements. Active display elements can control the emission or absorption of light, so that an active display element controls a display element to emit light or not to emit light or to absorb light or not to absorb light. For example, liquid crystal displays, organic light-emitting diode displays, inorganic light-emitting diode displays, and/or other light sources can be used as active display elements in embodiments of the present invention. Such active display elements and/or additional light sources may be used, for example, for nighttime illumination of the apparatus 5. The display elements can be electrically connected as are the photovoltaic elements using large-substrate photolithographic processes used in the display manufacturing industry. The display elements can be formed directly on the backplane substrate or can be formed on a separate substrate and then applied to the backplane substrate and electrically connected to a controller. Electrical interconnections can be formed directly on the backplane substrate (or layers formed on the backplane substrate), or include separate wires that are connected to an external controller.

A plurality of distinct display elements can be provided between or around the photovoltaic elements. Referring to the cross section of FIG. 2 and the top view of FIG. 6, a different display element can be associated with each photovoltaic element 20 and located around the photovoltaic element 20 on the backplane substrate 10. The cross section 7 of FIG. 6 corresponds to FIG. 2. In an alternative embodiment of the present invention (not shown), the associated display element can be arranged between the photovoltaic elements 20; other arrangements are possible as will be readily appreciated by one skilled in the display arts. As illustrated in FIGS. 2 and 6, three different display elements, 30R, 30G, and 30B are each located around a different photovoltaic element 20. FIG. 6 illustrates electrical connections 34 between the photovoltaic elements 20 and the display elements 30R, 30G, 30B and electrical connections 36 between the photovoltaic elements 30 and an external connection or controller (not shown). These different display elements 30R, 30G, 30B can be differently controlled by circuitry in the different photovoltaic elements 20 to emit or reflect light in a pattern to provide information to an off-axis viewer, for example variable text, images, or graphics. Display elements controlled by circuitry in a photovoltaic element 30 can include, for example, liquid crystals or light emitting diodes.

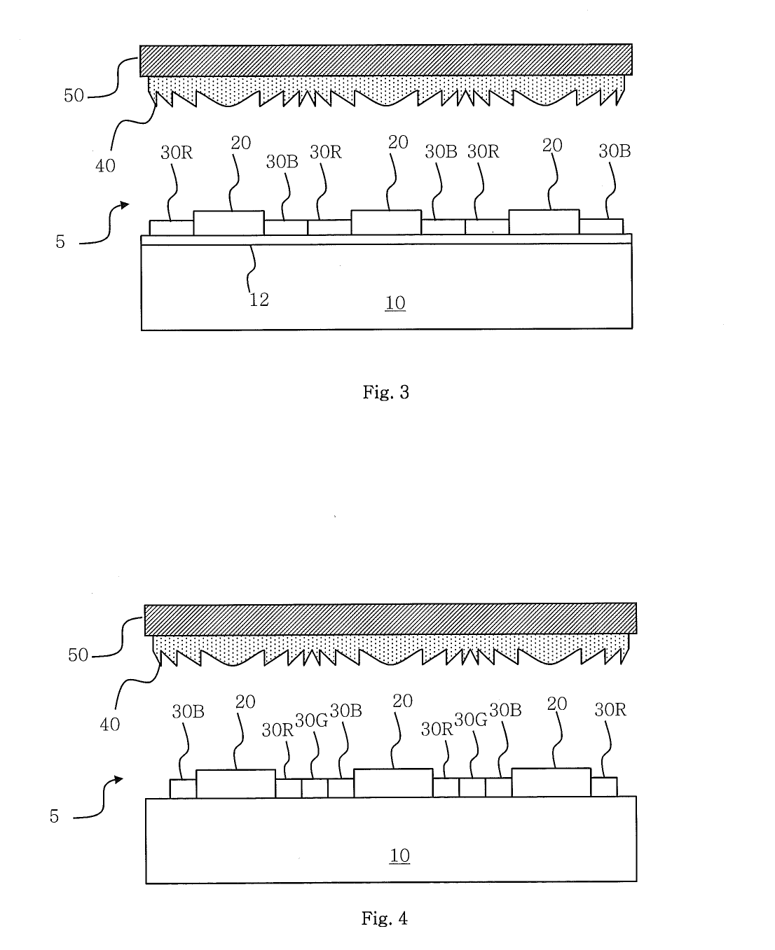

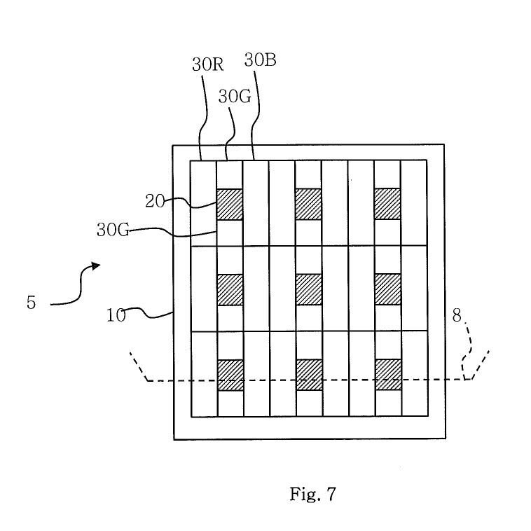

Another arrangement of display elements 30 is shown in the cross section of FIG. 3 and top view of FIG. 7. Cross section 8 shown in FIG. 7 corresponds to FIG. 3. Display elements 30R, 30G, and 30B are variously arranged between the photovoltaic elements 20. Referring to FIG. 4, display elements 30R, 30G, and 30B are arranged in stripes between the photovoltaic elements 20. These, and other, arrangements will be apparent to those skilled in the display art. For example, two, three, or more different display elements can be used.

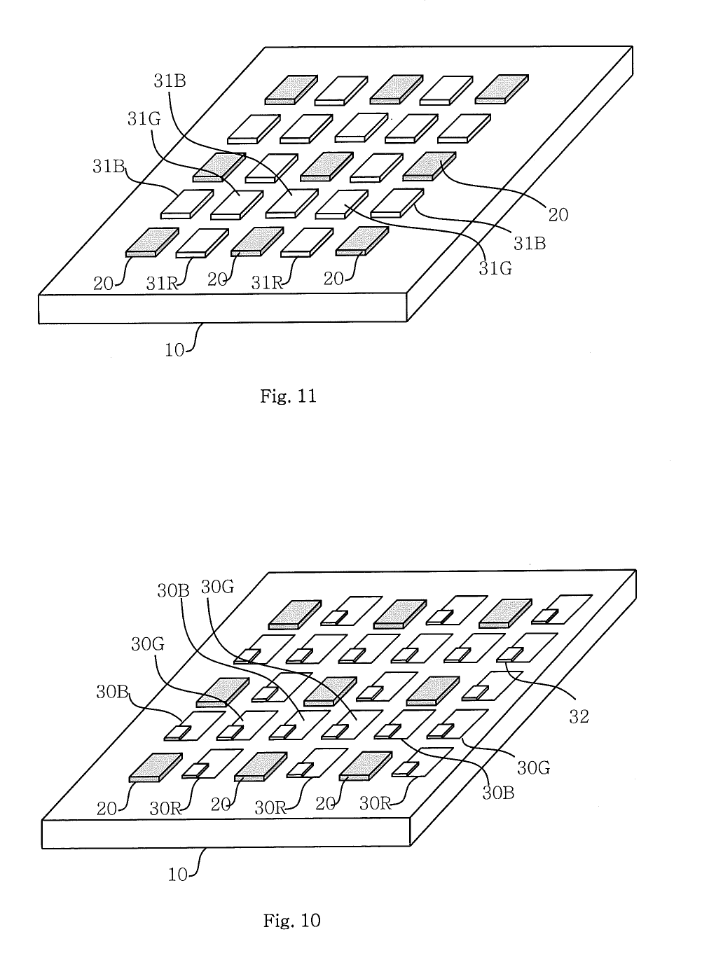

In one embodiment of the present invention, the display elements can be controlled externally using a passive-matrix control method. In an alternative embodiment of the present invention, additional circuitry can be provided on the backplane substrate to control display elements. As shown in FIG. 10, a backplane substrate 10 includes an array of photovoltaic elements 20 that convert incident sunlight into electrical power. Control circuits 32 control display elements 30R, 30G, and 30B. The display element control circuits 32 can be, for example, thin-film circuits or chiplets located on backplane substrate 10. Display elements 30R, 30G, and 30B can be liquid crystal elements that control the absorption of light or organic light emitting diode elements that emit light of the same color, for example white, or different colors, for example red, green, and blue. Each group of display elements 30R, 30G, and 30B can form a full-color pixel in a full-color display. In FIG. 10, the display elements 30R, 30G, and 30B and the photovoltaic elements 20 form multiple two-by-two arrays over the backplane substrate 10 but other arrangements are possible. In one embodiment of the present invention, the photovoltaic elements 20 are relatively sparse compared to the full-color pixel groups so that several full-color pixels are located between each photovoltaic element 20.

Referring to FIG. 11, the display elements can be inorganic light-emitting diodes formed in crystalline semiconductors. In one embodiment, all of the inorganic light-emitting diodes emit light of one color, for example white. In another embodiment, the inorganic light-emitting diodes 31R, 31G, 31B are spatially arranged in groups to form full-color pixels. The light-emitting diodes can be chiplets and can include control circuitry to control the inorganic light-emitting diodes 31R, 31G, 31B. In FIG. 11, the display elements 31R, 31G, and 31B and the photovoltaic elements 20 form a plurality of two-by-two arrays over the backplane substrate 10 but other arrangements are possible. In one embodiment of the present invention, the photovoltaic elements 20 are relatively sparse compared to the full-color pixel groups so that several full-color pixels can be located between each photovoltaic element 20.

Referring to FIG. 13, in an embodiment of the present invention, different images can be viewed at different off-axis angles with respect to the backplane substrate 10 normal. The optical element 40 can comprise an array of lenses, for example Fresnel lenses, arranged so that each lens is associated with one photovoltaic element 20 so that normally incident light rays A are directed onto the photovoltaic elements 20. The optical axis of the lenses are shown substantially parallel with the normally incident light rays A in FIG. 13. Emitted or reflected light rays X from display elements that are on one side of the optical axis of a lens are directed at a first angle to the normal angle by the optical element 40. Emitted or reflected light rays Y from display elements that are at a similar distance on the other side of the optical axis of a lens are directed by the lens at a second angle complementary to the first angle. Emitted or reflected light rays X and Y are formed by each of the display elements 30 and the corresponding lenses 42 in the array. Thus, viewers viewing the apparatus 5 at the left side of the normal or optical axis will see light rays X emitted by display element 30X while viewers viewing the apparatus 5 at the right side of the normal or optical axis will see light rays Y emitted by display element 30Y. Accordingly, the display elements 30X may provide portions of a first image that is visible to viewers viewing the apparatus 5 at the left side of the optical axis, and the display elements 30Y may provide portions of a second image that is visible to viewers viewing the apparatus 5 at the right side of the optical axis. The display elements 30× and/or 30Y may be passive or static display elements in some embodiments.

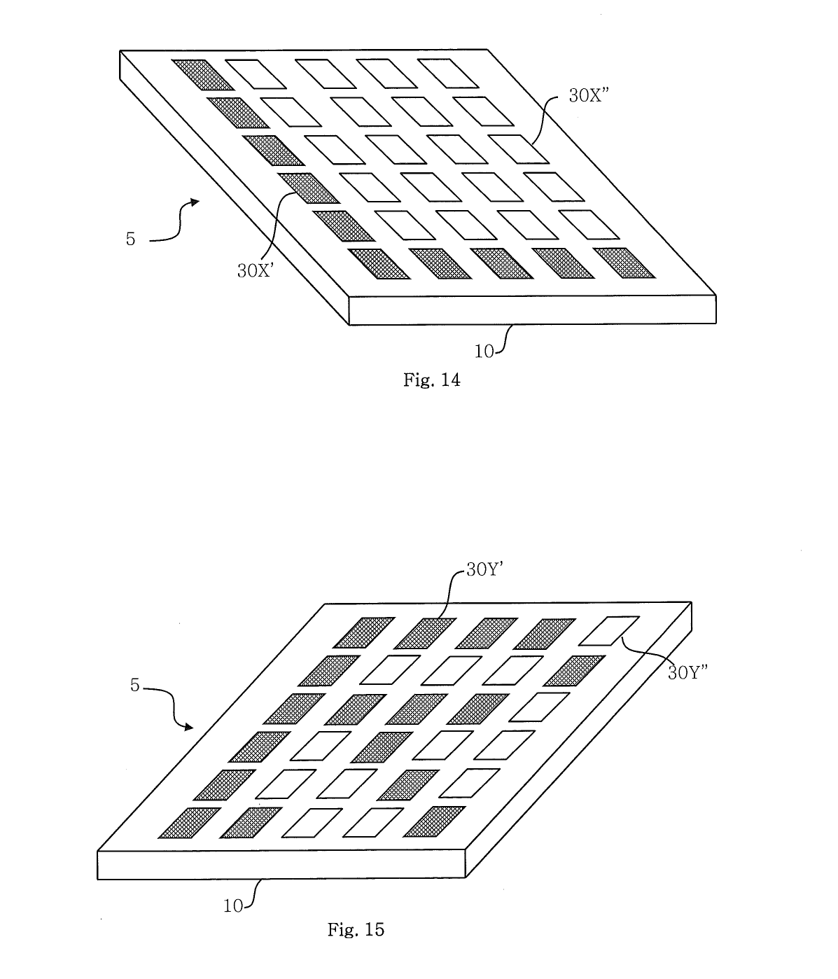

In other embodiments, the display elements 30X and 30Y may be active display elements. By controlling the display elements 30X differently from the display elements 30Y, different information can be displayed in the different directions. For example, referring to FIGS. 14 and 15, two different images can be shown at the same time from the same apparatus 5 at complementary angles to the normal with light rays corresponding to light rays X and Y of FIG. 13. As shown in FIG. 14, display elements 30X″ are controlled to not emit or reflect light while display elements 30X′ are controlled to emit or reflect light with light rays X (FIG. 13), forming the letter ‘L’ when viewed at the first angle. As shown in FIG. 15, display elements 30Y″ are controlled to not emit or reflect light while display elements 30Y′ are controlled to emit or reflect light with light rays Y (FIG. 13), forming the letter ‘R’ when viewed at the second angle complementary to the first angle.

While not shown in the Figures, depending on the distance between the optical element and the display elements, a plurality of different images corresponding to separately and/or differently controlled display elements between each photovoltaic element beneath a single Fresnel lens can be projected at a plurality of increasing angles. For example, it will be understood that additional display elements (each associated with a different image) may be included at various positions around each of the photovoltaic elements 20 such that each of the different images is visible depending on the angle of viewing. In other words, while illustrated with reference to two different images ‘L’ and ‘R’ in FIGS. 14 and 15, more than two different images may be displayed when viewed from various angles in some embodiments. In some embodiments, the different images may correspond to different image frames, to provide an appearance a moving image as the viewer's perspective relative to the apparatus 5 changes. Also, while illustrated as being immediately adjacent one another, it will be understood that there may be spacings and/or additional display elements provided between the display elements 30X and 30Y in some embodiments.

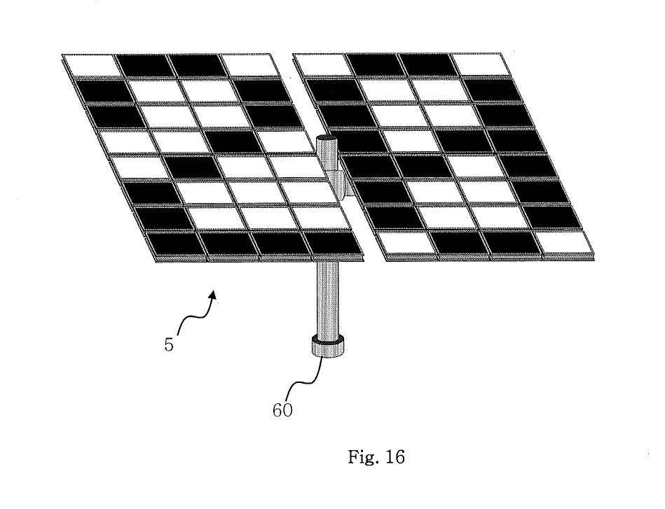

Referring to FIG. 16, the photovoltaic and display apparatus 5 of the present invention can be mounted on a support 60. By mounting the photovoltaic and display apparatus 5 on a support 60, a tracking system (not shown) can be employed to align the photovoltaic elements with incident light at a normal angle to increase the efficiency of the apparatus. In other words, the tracking system may be used to position the apparatus 5 such that the incident light is substantially parallel to an optical axis of the optical element(s) that focus the incident light onto the photovoltaic elements. Because a tracked system changes its orientation through the day to follow the location of the sun, for most of the day a viewer at a single location will see the photovoltaic and display apparatus at an off-axis angle, and will therefore see the display elements rather than the photovoltaic elements for the vast majority of the time, thereby providing the desired effect from the display elements. In an alternative arrangement, the photo-voltaic and display apparatus can have a fixed location and orientation. If viewed from an off-axis angle, the display elements can be seen from that off-axis angle.

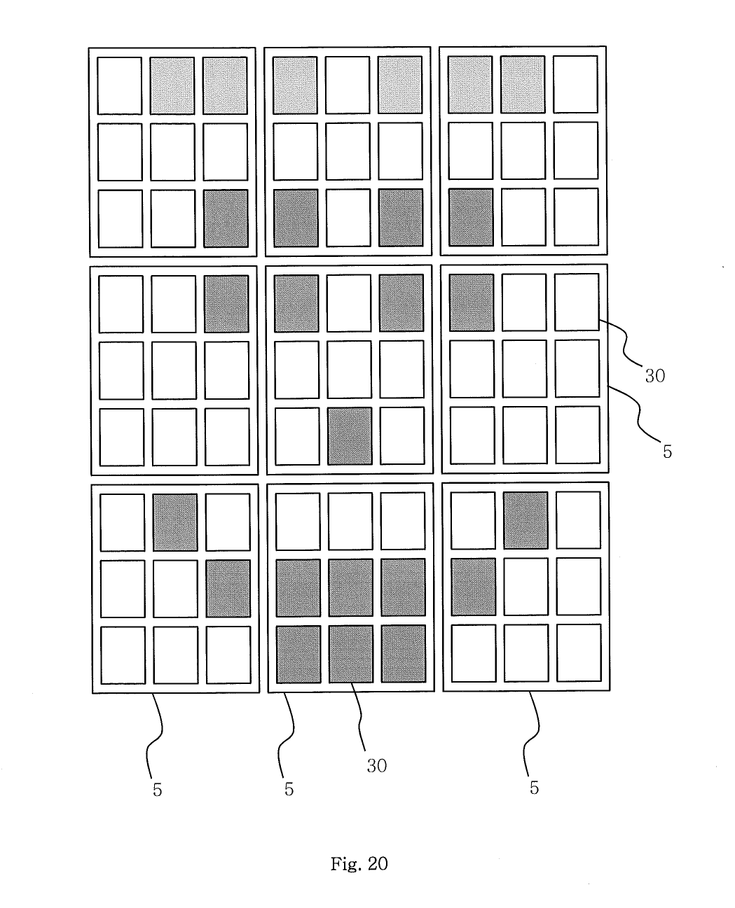

Although only a single concentrated photovoltaic and display apparatus is shown in FIG. 16, it will be apparent to those familiar with photovoltaic systems that a plurality of apparatuses can be used to form a larger solar cell array of separate modules 5, each collecting solar power to produce electricity, as shown in the top view of FIG. 20. By using multiple apparatuses, more power can be produced. The multiple apparatuses can be mounted to a common support and employ a common tracker or each apparatus can have an independent support and tracking device.

In an array of concentrated photovoltaic and display apparatuses, according to another embodiment of the present invention, the plurality of display elements on the plurality of concentrated photovoltaic and display apparatuses can be employed together to form a single image, so that the plurality of display elements in each concentrated photovoltaic and display apparatus displays a portion of an image, for example as illustrated in FIG. 20. FIG. 20 illustrates an array of concentrated photovoltaic and display apparatuses 5 arranged in a rectangular matrix. Each concentrated photovoltaic and display apparatuses 5 includes a plurality of display elements 30. The display elements 30 of each apparatus 5 may define a pixel or other portion of a single image such that, when viewed together, all of the display elements 30 from all of the concentrated photovoltaic and display apparatuses 5 of the array form a single image. Alternatively, each concentrated photovoltaic and display apparatus can display an individual image, either the same image or different images. In embodiments where the display elements 30 of each display apparatus 5 define the same image, a different portion of the same image may be provided by each apparatus 5 based on differences in viewer perspective to the array. In another arrangement, the plurality of concentrated photovoltaic and display apparatuses can together display a portion of an image.

The backplane substrate can be made from a variety of materials, including metal, glass, and polymer. Layers formed on the backplane substrate, for example polymer planarizing layers, can be made using photolithographic processes used in the flat-panel display industry. Likewise, patterned metal layers forming metal wires that electrically interconnect the photovoltaic and display elements to each other or to external connectors or control devices can be formed using photolithographic patterning methods (e.g. with photo curable resins exposed through masks and then differentially etched) or curable inks deposited in patterns by an inkjet micro-dispenser.

The steps of forming the various elements of the present invention can be performed in different orders, depending on the need of the manufacturing process and various embodiments of the present invention. For example, the display elements can be provided before or after the photovoltaic elements. The formation of electrical interconnections can be done at different stages of construction, either under or over a planarizing layer.

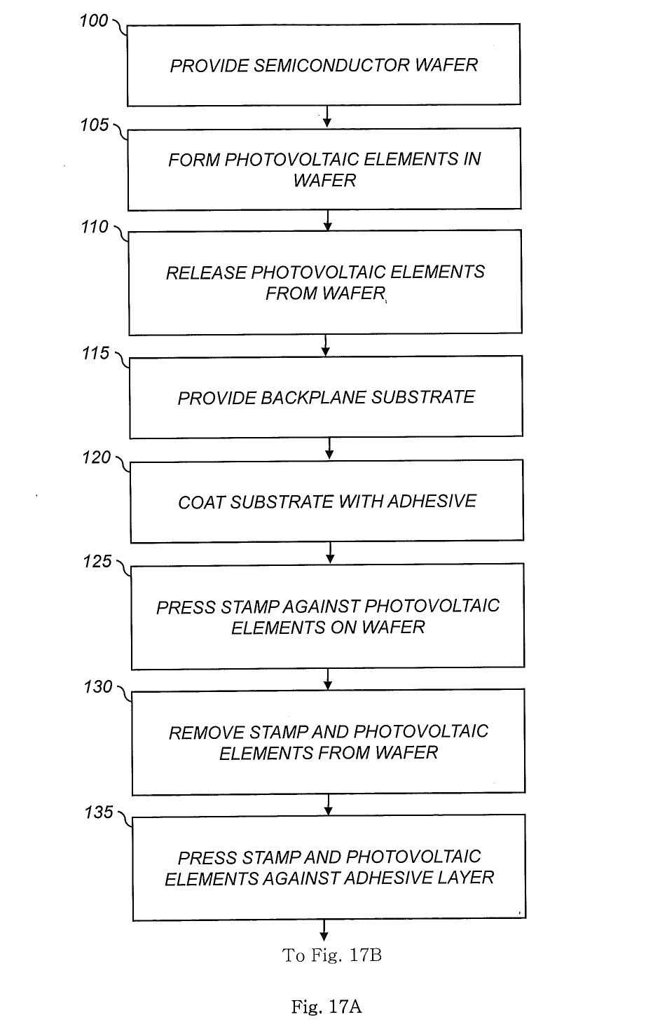

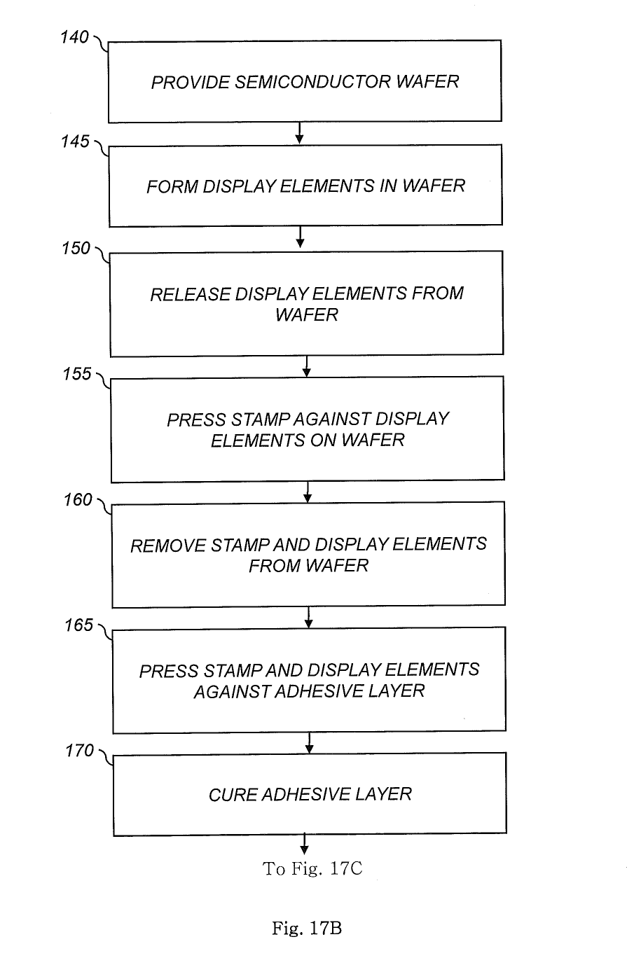

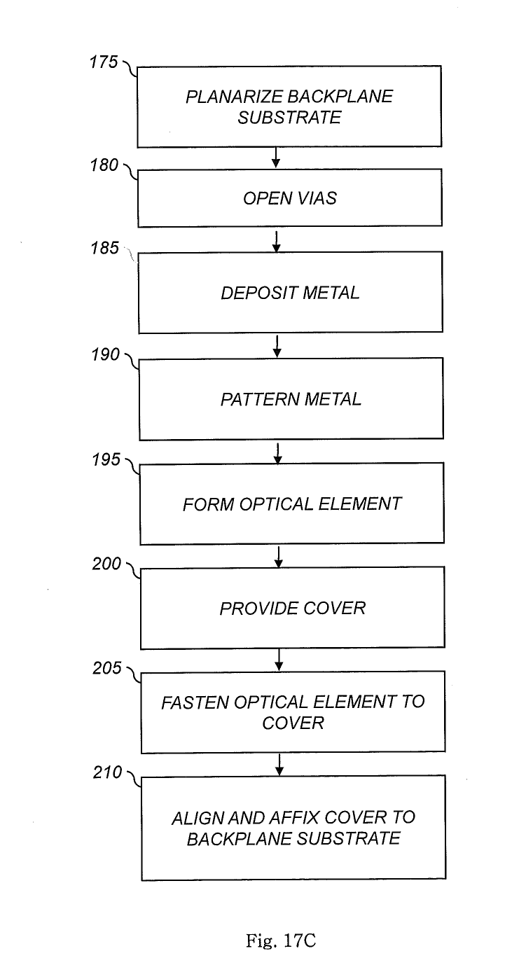

Referring to FIGS. 17A-17C, a printing process using a stamp to transfer active components such as small integrated circuit chiplets from a semiconductor wafer to a backplane substrate can be employed in an embodiment of the present invention. In such a process, a wafer is provided in step 100 and a sacrificial layer formed on the wafer. An active layer is then formed on the sacrificial layer. The wafer can be a semiconductor, for example crystalline silicon, gallium arsenide or another III-V compound semiconductor. These materials and layers can be deposited and processed using methods used in the photolithographic arts.

After the sacrificial layer and the active layer are deposited on the wafer, the wafer can be processed to form photovoltaic circuits in or on the active layer in step 105, for example using microfabrication foundry fabrication processes. Additional layers of material can be added as well as other materials such as metals, oxides, nitrides and other materials used in integrated-circuits. Each photovoltaic element can be a complete semiconductor integrated circuit chiplet and can include, for example, electronic or electro-optical circuits having transistors, capacitors, resistors, wires, light-emitting diodes, or photovoltaic elements. The photovoltaic elements can have different sizes, for example, 1000 square microns or 10,000 square microns, 100,000 square microns, or 1 square mm, or larger, and can have variable aspect ratios, for example 2:1, 5:1, or 10:1. The photovoltaic elements can have a thickness of 5-20 microns, 20-50 microns, or 50-100 microns.

The sacrificial layer is then removed, for example by etching with hydrofluoric acid to release the photovoltaic elements from the wafer in step 110, leaving the photovoltaic elements connected to the wafer by the breakable tethers.

A backplane substrate is provided in step 115 and coated with an adhesive layer 120. A stamp, for example made of polydimethylsiloxane (PDMS) and having protrusions matched to the location, size, and shape of each photovoltaic element is provided and then pressed in alignment against the top side of the released photovoltaic elements in step 125 to break the tethers and adhere the photovoltaic elements to the stamp protrusions. The stamp and photovoltaic elements are then removed from the wafer in step 130. The photovoltaic elements are aligned with the backplane substrate and adhered to the backplane substrate by pressing the active components against the backplane substrate in step 135. A curable adhesive can be located between the backplane substrate and the active components to assist in adhering the photovoltaic elements to the backplane substrate. As discussed above, a variety of display elements can be used in the present invention. Referring to FIG. 17B, in one embodiment, the display elements can be inorganic light-emitting diode chiplets or can be controlled by chiplet circuits formed in a semiconductor substrate. A semiconductor wafer is provided in step 140, and display element chiplets are formed in the wafer in step 145 and released from the wafer in step 150, as described above. A stamp shaped and sized to match the display element chiplets is aligned with and pressed against the wafer in step 155 and removed with the display element chiplets from the wafer in step 160. The stamp and display element chiplets are pressed against the adhesive layer and the display element chiplets adhered to the backplane substrate in step 165. The adhesive layer is then cured in step 170.

The process of making, removing, and adhering the display element chiplets is similar to that described for the photovoltaic elements. The steps of forming the display element chiplets and the photovoltaic elements can be done before, at the same time as, or after the backplane substrate is provided and coated with an adhesive layer. In one method, the photovoltaic elements and display element chiplets are made separately from the backplane substrate. The backplane substrate is then coated with the adhesive and the photovoltaic elements and display element chiplets are then stamped onto the adhesive layer.

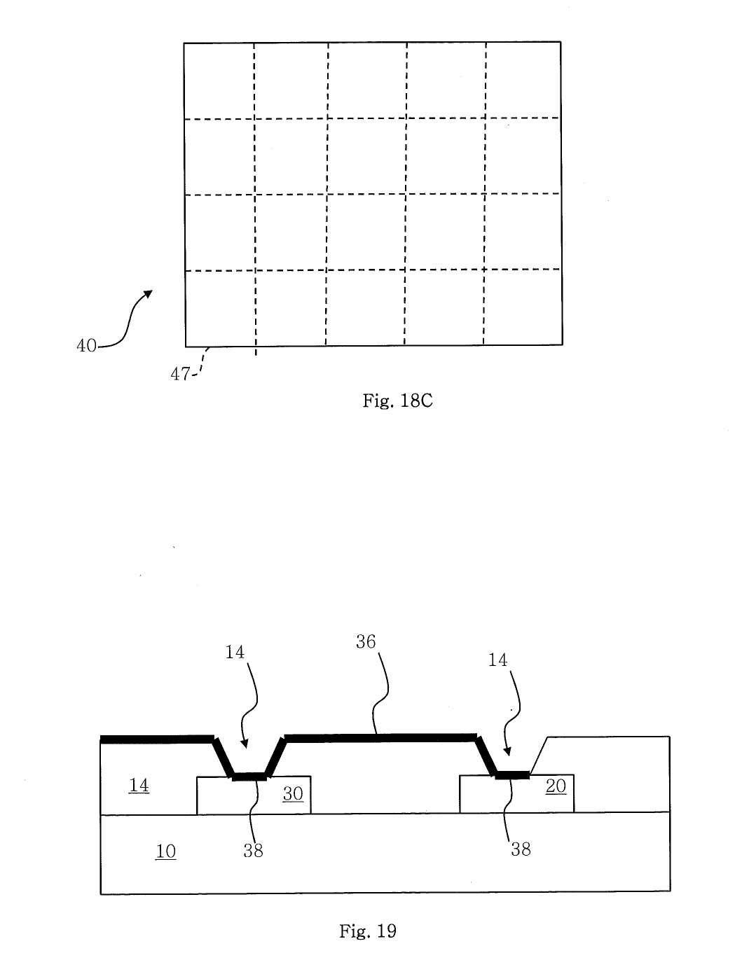

Referring also to FIG. 19, the backplane substrate 10 can be planarized to protect the display elements 30 and photovoltaic elements 20, for example by coating the backplane substrate, display element chiplets, and photovoltaic elements with a planarizing layer 14, for example comprising curable resin, in step 175. If necessary, vias 16 can be formed in the planarization layer 14 to open up electrical contacts 38 on the display element chiplets 30 and photovoltaic elements 20 in step 180. Vias can also be formed to expose optical elements, if desired, for example photo-sensitive areas on the photovoltaic elements or light-emitting areas on the display elements (not shown in FIG. 19). The electrical contacts 38 allow the display element chiplets 30 and photovoltaic elements 20 to be electrically controlled, for example by an external controller (not shown). A layer of electrically conductive metal is then coated over the planarization layer and vias in step 185 and then patterned in step 190 to form electrical connections 36 to the display element chiplets 30 and photovoltaic elements 20. Depending on the type of display elements and other design factors, additional layers can be provided, for example if organic light emitting diodes or liquid crystal displays are to be controlled by the display element chiplets.

If display elements and photovoltaic elements are both formed in chiplets, they may be formed on a common wafer and can be applied in a common layer, depending on the material and processing requirements of the display elements and the photovoltaic elements.

An optical element is made in step 195 as is a cover in step 200. The optical element can be adhered to the cover in step 205. The cover and optical element are aligned with and affixed to the backplane substrate in step 210 to complete the photovoltaic and display apparatus. The cover and optical element can be made separately from the display and photovoltaic elements and the backplane substrate. Additional power and control devices can be used to operate the apparatus. Processing steps, materials, and circuit designs from the display, integrated circuit, light-emitting diode, liquid crystal, organic light-emitting diode, and/or photolithographic arts may be used to construct and control the apparatus.

In an alternative embodiment of the present invention, the photovoltaic elements are surface-mountable integrated circuits that are surface mounted on the backplane substrate. Such surface mountable integrated circuits can be somewhat larger than the chiplets described above. In yet another alternative embodiment, photovoltaic integrated circuits are mounted on receiver substrate forming a photovoltaic element that is in turn affixed in alignment to a backplane substrate. Each photovoltaic element can also include an optical element or a display element. Alternatively, each receiver substrate can include a plurality of photovoltaic integrated circuits.

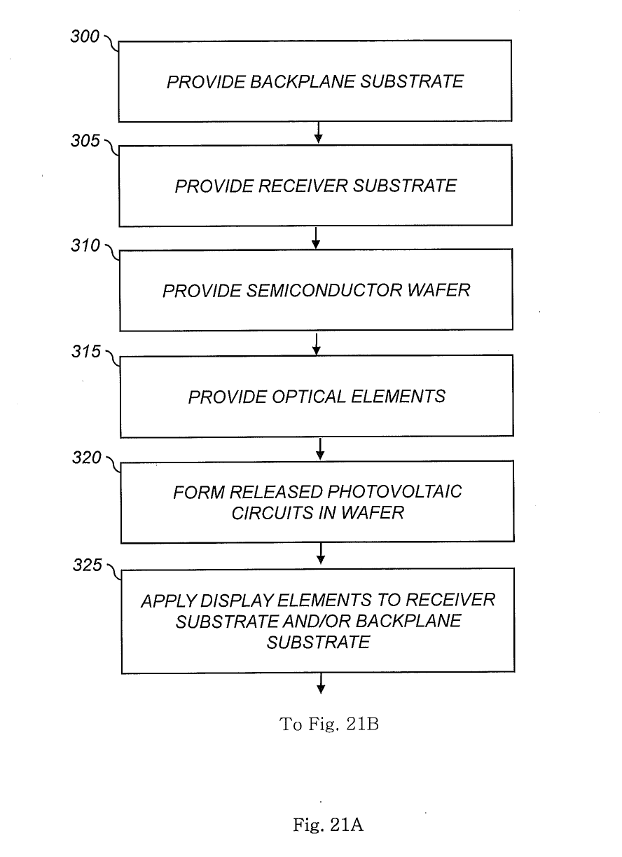

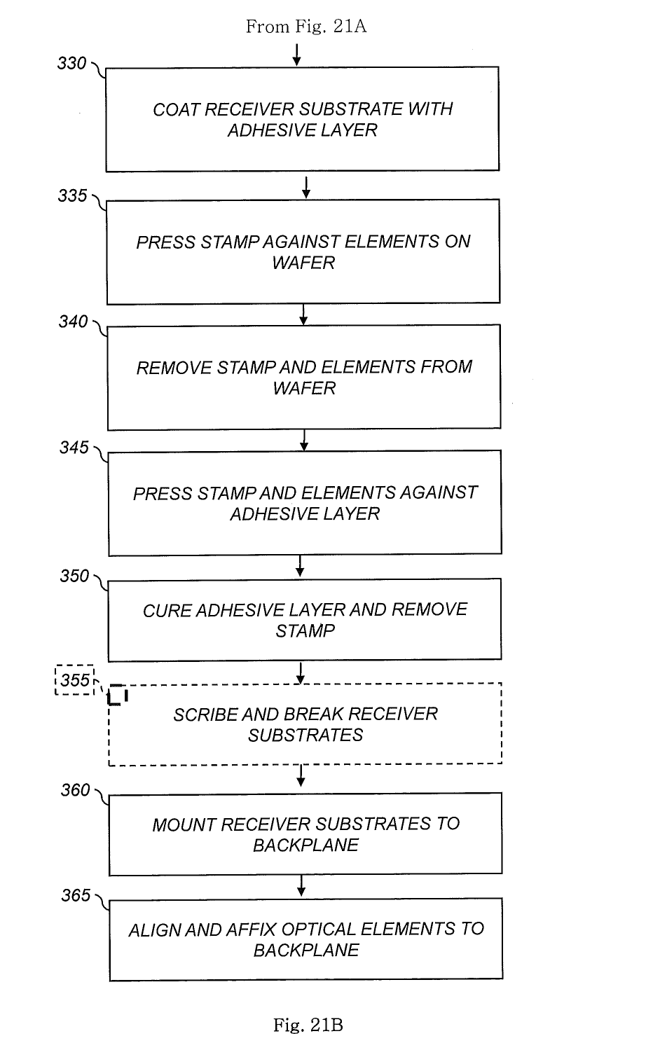

A method of making an apparatus according to an alternative embodiment of the present invention is illustrated in the flow diagram of FIGS. 21A and 21B. Referring to FIG. 21A, a backplane substrate is provided in step 300, a receiver substrate in step 305, a semiconductor wafer in step 310 and optical elements in step 315.

These steps can be done independently and in any order. Once the wafer is provided (step 310), photovoltaic circuits are formed in the wafer and then released in step 320, for example as described above with respect to steps 100 to 110 of FIG. 17A.

Display elements are applied to the receiver substrate, the backplane substrate, or both in step 325. This step can be done independently of the wafer processing. It can also be done after steps 350, 355, or 360 below. As noted above, the display elements can be completely passive elements such as a reflective layer or they can be controllable elements. Passive elements can be patterned over the backplane or receiver substrates. The backplane and receiver substrates can be patterned differently or have different display elements.

The receiver substrate is coated with an adhesive layer in step 330. A stamp is pressed against the photovoltaic elements on the wafer (step 335), removed from the wafer in step 340, and the stamp and photovoltaic elements pressed against the adhesive layer on the receiver substrate in step 345. These steps are similar to those of FIGS. 17A-17C, with the exception that the photovoltaic elements are adhered to the receiver substrate rather than to the backplane substrate. The adhesive layer can be cured to affix the photovoltaic elements to the receiver substrate and the stamp removed in step 350. In one embodiment of the present invention, a plurality of photovoltaic circuits are stamped onto a single large receiver substrate. The single large receiver substrate is then divided (for example by scribing and breaking) into individual receiver substrates (optional step 355). Each receiver substrate could have one or a plurality of photovoltaic circuits located thereon. If only one photovoltaic circuit is located on each receiver substrate, each receiver substrate and photovoltaic circuit forms an individual photovoltaic element The receiver substrates are then mounted to the backplane (in step 360) and connected with any electrical connections necessary to control the display elements and collect current from the photovoltaic elements. The optical elements can be aligned and affixed to the backplane in step 365. As with the integration of the display elements (step 325), the integration of the optical elements can be done at various stages of process, for example before the receiver substrates are mounted (step 355) or before the display elements are mounted (step 325).

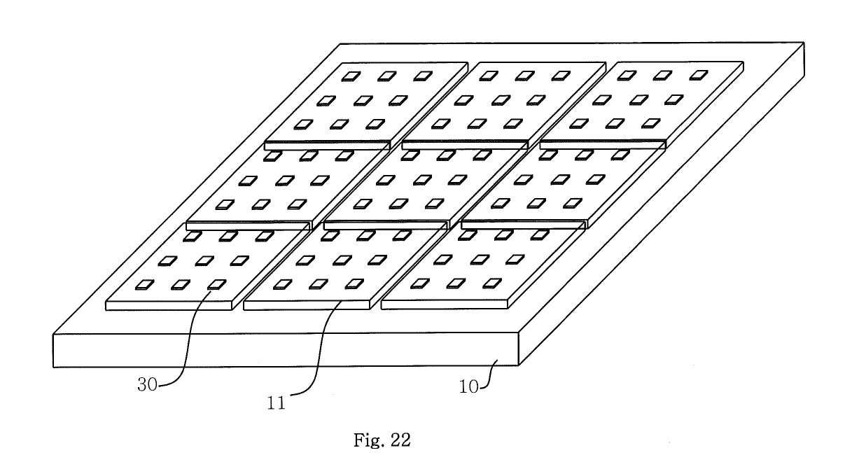

In one embodiment, multiple receiver substrates are mounted on the backplane substrate and multiple photovoltaic elements are adhered to each receiver substrate. The receiver substrates can include display elements and may cover a significant portion of the backplane substrate. Alternatively, the receiver substrates may cover only a minor portion of the backplane substrate and the display elements can be formed directly on the backplane substrate. In either case, the photovoltaic elements are distributed over the backplane substrate. The display elements can be formed on the receiver substrate or the backplane substrate, or both the receiver substrate and the backplane substrate. FIG. 22 illustrates a backplane substrate 10 with an array of receiver substrates 11 affixed to the backplane substrate 10, each receiver substrate including multiple display elements 30 and photovoltaic elements (not shown).

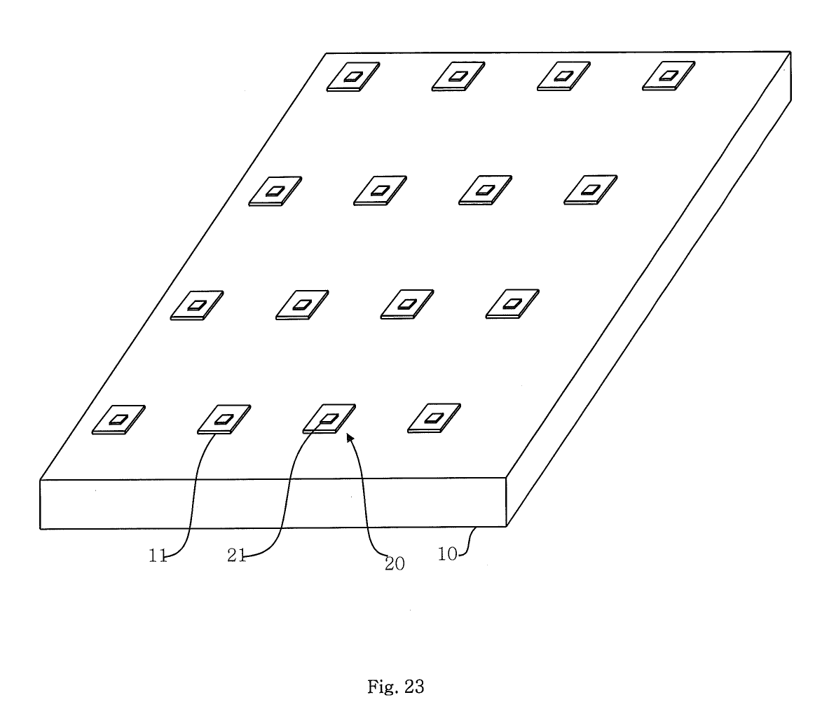

In an alternative embodiment, illustrated in FIG. 23, a backplane substrate 10 includes an array of receiver substrates 11 affixed to the backplane substrate 10, each receiver substrate 11 including a single photovoltaic circuit 21, for example a photovoltaic integrated circuit chiplet. As is apparent from these embodiments, a photovoltaic element can include a photovoltaic circuit in an integrated circuit or a photovoltaic circuit mounted on a receiver substrate that is in turn mounted on a backplane substrate.

The method described provides the advantage of a high-performance backplane substrate with a reduced number of layers and process steps. Processing technologies for these materials typically employ high heat and reactive chemicals. However, by employing transfer technologies that do not stress the active components or backplane substrate materials, more benign environmental conditions can be used compared to thin-film transistor manufacturing processes. Thus, the present invention has an advantage in that flexible substrates (e.g. polymer substrates) that are typically intolerant of extreme processing conditions (e.g. heat, chemical, or mechanical processes) can be employed for the backplane substrate. Furthermore, it has been demonstrated that crystalline silicon substrates have strong mechanical properties and, in small sizes, can be relatively flexible and tolerant of mechanical stress. This is particularly true for substrates of 5 micron, 10 micron, 20 micron, 50 micron, or even 100-micron thicknesses.

In comparison to thin-film manufacturing methods, using densely populated active substrates and transferring active components to a backplane substrate that requires only a sparse array of active components located thereon does not waste or require active layer material on a backplane substrate. The present invention is also useful in transferring active components made with crystalline semiconductor materials that have much higher performance than thin-film active components. Furthermore, the flatness, smoothness, chemical stability, and heat stability requirements for a backplane substrate useful in the present invention are greatly reduced because the adhesion and transfer process is not significantly limited by the backplane substrate material properties. Manufacturing and material costs are reduced because of high utilization rates of expensive materials (e.g. the active substrate) and reduced material and processing requirements for the backplane substrate.

The photovoltaic and display apparatus according to embodiments of the present invention provides a high-performance and efficient photovoltaic apparatus and a visible display element on the same backplane. The display element can be used to improve the visual appearance of the apparatus, to camouflage the apparatus, and/or to communicate information. The communication can be passive and fixed or active and controlled to change over time. Different communications can be directed in different directions.

The invention has been described in detail with reference to particular embodiments thereof, but it will be understood that variations and modifications can be effected within the spirit and scope of the invention.

1. A concentrated photovoltaic and display apparatus, comprising:
a backplane substrate;
a plurality of photovoltaic elements distributed over the backplane substrate;
a plurality of display elements distributed over the backplane substrate between the photovoltaic elements; and
a concentrating optical element positioned over the backplane substrate, the photovoltaic elements, and the display elements, wherein:
the optical element is configured to concentrate incident light propagating in a direction substantially parallel to an optical axis thereof away from the display elements and onto the photovoltaic elements; and
the optical element is configured to direct light reflected or emitted from the display elements in one or more directions that are not substantially parallel to the optical axis thereof such that the photovoltaic elements are not substantially visible when viewed at angles of about 2 degrees and more with respect to the optical axis.

2. The apparatus of claim 1, wherein the optical element includes a Fresnel lens, an array of Fresnel lenses, a lens, an array of lenslets, a plano-convex lens, an array of plano-convex lenses, a double-convex lens, an array of double-convex lenses, or an array of crossed panoptic lenses.

3. The apparatus of claim 1, wherein the photovoltaic elements and the display elements are arranged on coplanar surfaces of the backplane substrate.

4. The apparatus of claim 3, wherein the display elements are visible when viewed at the angles of about 2 degrees and more with respect to the optical axis.

5. The apparatus of claim 4, wherein the optical element is configured to magnify the photovoltaic elements when viewed along the direction substantially parallel to the optical axis, and to magnify the display elements when viewed along the one or more directions that are not substantially parallel to the optical axis.

6. The apparatus of claim 5, wherein the optical element is configured to concentrate the incident light propagating in the direction substantially parallel to the optical axis by about 1000 times or more.

7. The apparatus of claim 6, wherein the optical element includes a spherical lens.

8. The apparatus of claim 6, wherein the photovoltaic elements are arranged in an array on the backplane substrate, wherein the optical element further includes an array of lenses, wherein each of the lenses focuses the incident light that is substantially parallel to a respective optical axis thereof onto a corresponding one of the photovoltaic elements, and wherein the display elements are positioned alongside the photovoltaic elements on the substrate in areas between respective focal points of the lenses.

9. The apparatus of claim 1, further comprising:
a plurality of receiver substrates mounted on the backplane substrate,
wherein one or more of the photovoltaic elements and/or the display elements are arranged on each of the receiver substrates.

10. The apparatus of claim 9, wherein each of the receiver substrates includes a single photovoltaic circuit.

11. The apparatus of claim 1, wherein each of the photovoltaic elements is adjacent first and second ones of the display elements that are arranged at different positions relative to the optical axis, wherein the first ones of the display elements are associated with a first image, wherein the second ones of the display elements are associated with a second image, and wherein the first and second images are visible from different nonzero angles with respect to the optical axis.

12. The apparatus of claim 1, wherein the display elements are passive reflectors.

13. The apparatus of claim 12, wherein the display elements include an acrylic-epoxy blend.

14. The apparatus of claim 1, wherein the display elements are active controllable elements.

15. The apparatus of claim 14, wherein the display elements can be respectively controlled to emit light or to not emit light.

16. The apparatus of claim 14, wherein the display elements can be respectively controlled to absorb light or to reflect light.

17. The apparatus of claim 14, wherein each of the photovoltaic elements is adjacent three of the display elements that are configured to provide light of three different colors, respectively.

18. The apparatus of claim 17, wherein the three of the display elements are spatially grouped into full-color pixels.

19. The apparatus of claim 14, wherein the display elements are controlled by circuits in the photovoltaic elements.

20. The apparatus of claim 1, wherein the photovoltaic elements and/or the display elements comprise printable chiplets.

21. The apparatus of claim 1, wherein the apparatus comprises one of a plurality of modules of an array that is configured to display a single image across the plurality of modules, and wherein the display elements of the apparatus provide a portion of the single image.

22. The apparatus of claim 21, wherein the array including the plurality of modules is mounted on a common support, and further comprising:
a tracking system including the array mounted thereon, wherein the tracking system is configured to move the common support to orient the modules of the array such that the optical axes of the respective optical elements thereof are substantially parallel to the incident light.

23. The apparatus of claim 21, wherein one or more of the plurality of display elements of each of the modules define a different portion of the single image that is visible when viewed along the direction that is not substantially parallel to the respective optical axis of the optical element thereof.

24. The apparatus of claim 23, wherein one or more of the plurality of display elements of each of the backplane substrates define an entirety of the single image, and wherein a different portion of the single image is provided by each of the module based on differences in viewer perspective to the array.

25. A method of fabricating a concentrated photovoltaic and display apparatus, the method comprising:
providing a backplane substrate;
providing a plurality of photovoltaic elements distributed over the backplane substrate;
providing a plurality of display elements distributed over the backplane substrate between the photovoltaic elements; and
providing a concentrating optical element over the backplane substrate, the photovoltaic elements, and the display elements, wherein:
the optical element is configured to concentrate incident light propagating in a direction substantially parallel to an optical axis thereof away from the display elements and onto the photovoltaic elements; and
the optical element is configured to direct light reflected or emitted from the display elements in one or more directions that are not substantially parallel to the optical axis of the optical element such that the photovoltaic elements are not substantially visible when viewed at angles of about 2 degrees and more with respect to the optical axis.

26. The method of claim 25, wherein providing the plurality of photovoltaic elements on the backplane substrate comprises:
forming the plurality of photovoltaic elements in a wafer;
releasing the photovoltaic elements from the wafer;
adhering the photovoltaic elements to a stamp; and
stamping the photovoltaic elements onto the backplane substrate.

27. The method of claim 25, wherein providing the plurality of photovoltaic elements on the backplane substrate comprises:
forming the plurality of photovoltaic elements in a wafer;
releasing the photovoltaic elements from the wafer;
adhering the photovoltaic elements to a stamp;
stamping the photovoltaic elements onto one or more receiver substrates; and
affixing the one or more receiver substrates to the backplane substrate.

28. The method of claim 27, wherein stamping the photovoltaic elements onto one or more receiver substrates comprises:
stamping the photovoltaic elements onto a single receiver substrate; and
breaking the single receiver substrate into a plurality of individual receiver substrates,
wherein affixing the one or more receiver substrates comprises affixing the individual receiver substrates to the backplane substrate.

29. The method of claim 28, wherein each of the individual receiver substrates includes a single photovoltaic circuit, and wherein the individual receiver substrate and the single photovoltaic circuit define one of the photovoltaic elements.

30. A photovoltaic device, comprising:
a substrate including a photovoltaic element and at least one display element arranged alongside one another on a surface of the substrate; and
a concentrating optical element positioned over the surface of the substrate and aligned such that the photovoltaic element is substantially centered about an optical axis thereof to direct incident light propagating on-axis with respect to the optical axis away from the at least one display element and onto the photovoltaic element, and to direct light reflected or emitted from the at least one display element off-axis with respect to the optical axis such that the photovoltaic element is not substantially visible when viewed at angles of about 2 degrees and more with respect to the optical axis.

31. The device of claim 30, wherein the display element is visible when viewed at the angles of about 2 degrees and more with respect to the optical axis.

32. The device of claim 31, wherein the optical element is configured to magnify the photovoltaic element when viewed on-axis, and to magnify the display element when viewed off-axis.

33. The device of claim 32, wherein the optical element is configured to concentrate the incident light propagating on-axis by about 1000 times or more.

34. The device of claim 33, wherein the optical element includes a spherical lens.

35. The device of claim 33, wherein:
the photovoltaic element comprises one of a plurality of photovoltaic elements arranged in an array on the surface of the substrate; and
the optical element includes an array of lenses, wherein each of the lenses focuses the incident light propagating on-axis with respect to a respective optical axis thereof onto a corresponding one of the photovoltaic elements.

36. The device of claim 35, wherein the at least one display element comprises a plurality of display elements positioned alongside the photovoltaic elements on the surface of the substrate in areas between respective focal points of the lenses.

37. The device of claim 36, wherein the photovoltaic elements occupy a smaller area of the surface of the substrate than the display elements.

38. The device of claim 37, wherein the photovoltaic elements occupy less than about 5% of the area of the surface of the substrate.

39. The device of claim 36, further comprising:
a tracking system including the substrate mounted thereon, wherein the tracking system is configured to orient the substrate such that the incident light is propagating on-axis with respect to the respective optical axes of the lenses.

40. The device of claim 30, wherein the photovoltaic element and the display element are arranged on coplanar surfaces of the substrate.

41. The device of claim 40, wherein the coplanar surfaces of the substrate are positioned at a focal plane of the optical element.

42. The device of claim 30, wherein the photovoltaic element is adjacent first and second display elements, wherein the first display element is associated with a first image, wherein the second display element is associated with a second image, and wherein the first and second images are visible from different off-axis angles with respect to the optical axis.
